(19) United States
(12) Patent Application Publication
(10) Pub. No.: US 2004/0113698 A1
(43) Pub. Date: Jun. 17, 2004

(54) Signal amplifier using a doherty amplifier

(75) Inventors: Bumman Kim, Kyungsangbuk-do (KR); Youngoo Yang, Kyungsangbuk-do (KR)

Correspondence Address: McGuireWoods, Suite 1800, 1750 Tysons Boulevard, McLean, VA, 22102-4215, US

(73) Assignee: Postech Foundation

(21) Appl. No.: 10/618,772

(22) Filed: Jul. 15, 2003

(30) Foreign Application Priority Data
Nov. 18, 2002 (KR) 2002-71537

(51) Int. Cl. H03F 3/68

(52) U.S. Cl. 330/295

(57) ABSTRACT

A signal amplifier includes a splitter for splitting an input signal into first and second signals, first and second bias control networks for generating a base bias signal for a Doherty amplifier in accordance with a power level of the input signal, a carrier amplifier for amplifying the first input signal, a peaking amplifier for amplifying the second input signal and a Doherty output network for combining the amplified signals. Through a simplified transformation of characteristic impedances in the Doherty output network, minimization of circuitry including the signal amplifier is obtained. Further, by controlling the Doherty amplifier in accordance with the power level of the input signal, both high efficiency and high linearity of the signal amplifier are achieved.

### FIELD OF THE INVENTION

The present invention relates to a signal amplifier; and, more particularly, to a signal amplifier employing a Doherty amplifier suitable for use in a mobile communications terminal.

### BACKGROUND OF THE INVENTION

As is well known in the art, a Doherty amplifier is a high efficiency amplifier capable of performing an input and output impedance matching process. The Doherty amplifier generally uses two amplifiers, a carrier amplifier and a peaking amplifier, and controls the load line impedance of the carrier amplifier, depending on the power level of an input signal and the amount of current provided from the peaking amplifier to the load line. To attain such a high efficiency performance over a wide input signal bandwidth, the Doherty amplifier employs a technique where the carrier amplifier and the peaking amplifier are connected in parallel to each other by a quarter-wave transmission line (λ/4 line)

The Doherty amplifier was used in earlier days as an amplitude modulation (AM) transmitter of a broadcasting apparatus using a high-power low-frequency/middle-frequency (LF/MF) vacuum tube. Then, various suggestions have been made to apply the Doherty amplifier to a solid-state high-power transmitter.

In FIG. 1, there is provided a signal amplifier using a conventional Doherty amplifier.

As shown in FIG. 1, the signal amplifier includes a splitter 10, a transmission line 15, a Doherty amplifier 20, a first load line 30 and a second load line 40. The Doherty amplifier 20 has a carrier amplifier 23 and a peaking amplifier 24. Further, the carrier amplifier 23 includes an input matching circuit 21 and a transistor 22; and the peaking amplifier 24 similarly includes an input matching circuit 21′ and a transistor 22′.

In the conventional Doherty amplifier, an input signal is split into two signals at the splitter 10 and inputted into the Doherty amplifier 20. One of the two signals is fed to the carrier amplifier 23 and the other signal is delayed by the transmission line 15 having characteristic impedance Zₐ and then fed to the peaking amplifier 24. The delay of the signal may be adjusted so that the input of the peaking amplifier 24 lags the input of the carrier amplifier 23 by 90 degrees.

The transistors 22 and 22′ of the carrier amplifier 23 and the peaking amplifier 24 are respectively fed with a predetermined base bias voltage regardless of the power level of the input signal. The peaking amplifier 24 provides current to the second load line 40 according to the power level of the input signal. As the amount of the current supplied to the second load line 40 varies, the impedance of the first load line 30 placed at an output of the carrier amplifier 23 is adjusted so as to control the efficiency of the Doherty amplifier 20. Two quarter-wave transmission lines having characteristic impedances Zₘ and Z_{b} may be used for the first and second load lines 30 and 40 placed at the outputs of the carrier amplifier 23 and the peaking amplifier 24, respectively.

Then, the signals transmitted respectively from the first load line 30 and the peaking amplifier 24 are combined at a combination circuit common node 50 and outputted through the second load line 40.

However, because the aforementioned Doherty amplifier should use an additional quarter-wave transmission line to transform an output impedance to match with 50 Ω, wherein 50 Ω is a traditional setting for an output impedance, its substantial circuit size tends to be large. For this reason, there is a limitation in using the conventional Doherty amplifier in a mobile communications terminal where the size of a circuit including the amplifier is critical.

And also, because a constant bias voltage is fed to both the carrier amplifier and the peaking amplifier regardless of the power level of the input signal, the conventional Doherty amplifier is not suitable for application in mobile communications terminals where an input signal frequency varies in a wide range.

### SUMMARY OF THE INVENTION

It is, therefore, a primary object of the present invention to provide a signal amplifier for achieving high linearity and high efficiency by providing a Doherty amplifier with a bias signal varying in accordance with a power level of an input signal and for achieving minimization of the signal amplifier by controlling a characteristic impedance of a Doherty output network arranged at an output of the Doherty amplifier.

In accordance with a preferred embodiment of the present invention, there is provided a signal amplifier using a Doherty amplifier, the signal amplifier including a splitter for splitting an input signal into two signals to be transmitted respectively through a first and a second transmission paths; a first and a second bias control networks for generating bias signals corresponding to a power level of the input signal by alternating its operation modes, wherein the power level of the input signal lower than a predetermined threshold level is associated with a low input power drive mode and the power level of the input signal higher than the predetermined threshold level is associated with a high input power drive mode; a Doherty amplifier including a carrier amplifier for amplifying the signal transmitted through the first transmission path and a peaking amplifier for amplifying the signal transmitted through the second transmission path; and a Doherty output network for matching and outputting signals amplified at the carrier amplifier and the peaking amplifier.

### BRIEF DESCRIPTION OF THE DRAWINGS

The above and other objects and features of the present invention will become apparent from the following description of a preferred embodiment given in conjunction with the accompanying drawings, in which:

FIG. 1 is a circuit diagram showing a signal amplifier using a conventional Doherty amplifier;

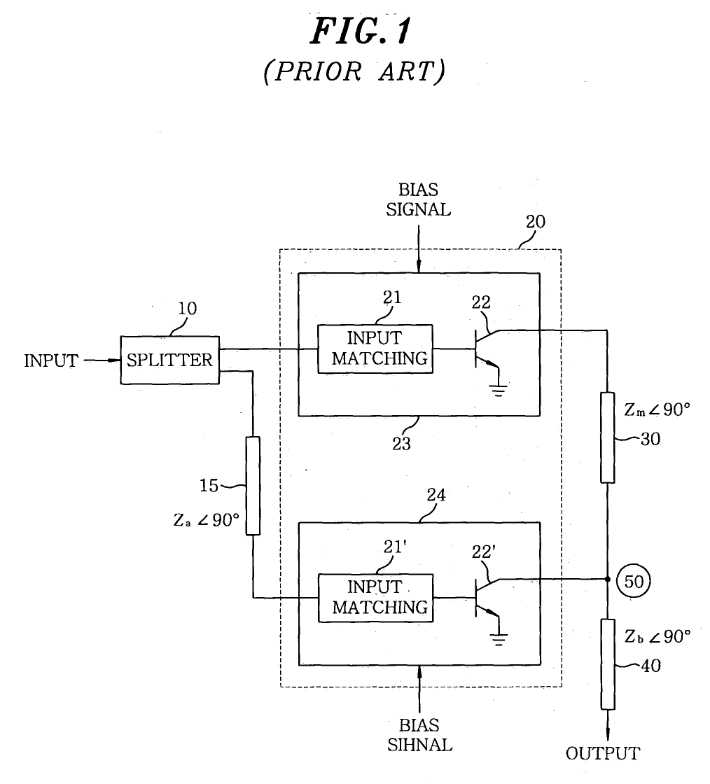

FIG. 2 depicts a circuit diagram showing a signal amplifier using a Doherty amplifier in accordance with a preferred embodiment of the present invention; and

FIG. 3 provides a graph showing an efficiency of the signal amplifier using the Doherty amplifier in accordance with the preferred embodiment of the present invention.

### DETAILED DESCRIPTION OF THE PREFERRED EMBODIMENTS

The preferred embodiment of the present invention will now be described in detail with reference to the accompanying drawings.

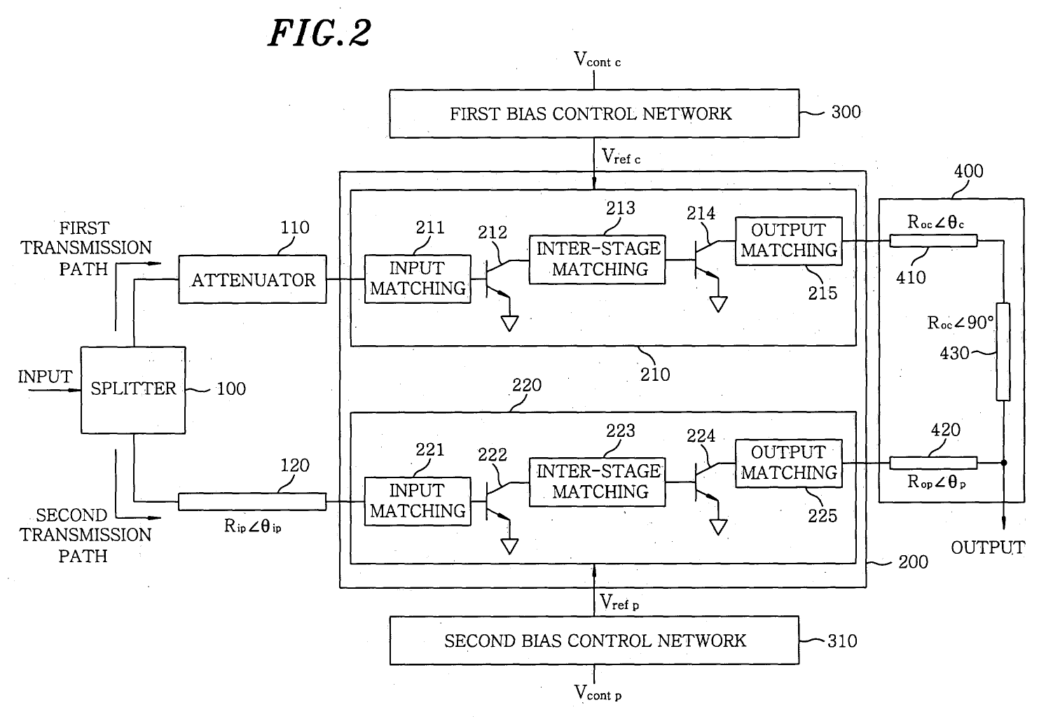

FIG. 2 illustrates a circuit diagram showing a signal amplifier using a Doherty amplifier in accordance with the preferred embodiment of the present invention. As shown in FIG. 2, the signal amplifier includes a splitter 100, an attenuator 110, a first transmission line 120, a Doherty amplifier 200, a first and a second bias control networks 300 and 310, and a Doherty output network 400. The Doherty amplifier 200 includes a carrier amplifier 210 and a peaking amplifier 220. The carrier amplifier 210 has an input matching circuit 211, a driving transistor 212, an inter-stage matching circuit 213, an output transistor 214, and an output matching network 215. Likewise, the peaking amplifier 220 has an input matching circuit 221, a driving transistor 222, an inter-stage matching circuit 223, an output transistor 224, and an output matching network 225. Although the carrier amplifier 210 and the peaking amplifier 220 constructing the Doherty amplifier 200 are described respectively as a two-stage structure having two transistors in FIG. 2, it will be understood by the one skilled in the art that it can be configured in a single-stage or more-than-two-stage structure.

Meanwhile, the splitter 100 may be implemented by using a Wilkinson divider or other passive elements to split an input signal into two signals to be transmitted respectively through two transmission paths, i.e., a first transmission path and a second transmission path, wherein the attenuator 110 and the carrier amplifier 210 are located on the first transmission path and the first transmission line 120 and the peaking amplifier 220 are located on the second transmission path.

Further, the attenuator 110 may be implemented by using passive elements such as resistors or active elements such as variable gain amplifiers (VGAs), which are arranged on the first transmission path prior to the carrier amplifier 210. The attenuator 110 attenuates the signal transmitted from the splitter 100 and feeds it to the carrier amplifier 210, thereby compensating a gain difference between the first and the second transmission paths. Although the attenuator 110 is placed at an input end of the carrier amplifier 210 on the first transmission path in this embodiment, alternatively, it can be placed at an input end of the peaking amplifier 220 on the second transmission path.

The first transmission line 120 is located between the splitter 100 and the peaking amplifier 220 for compensating a time delay and a phase delay between signals transmitted on the first and the second transmission paths, wherein the first transmission line 120 is an offset transmission line having characteristic impedance Rᵢₚ and phase θᵢₚ, which may be changed appropriately to compensate the time and phase differences. Further, the first transmission line 120 may be implemented by using lumped elements.

On the other hand, the first bias control network 300 has a V_{contC} pin for receiving a control voltage varying with the power level of the input signal and a V_{refC} pin for providing the carrier amplifier 210 with a base bias voltage varying with the control voltage received at the V_{contC} pin. Further, the second bias control network 310 has a V_{contP} pin for receiving a control voltage whose level is equal to that of the control voltage fed to the V_{contC} pin and a V_{refP} pin for providing the peaking amplifier 220 with a base bias voltage varying with the voltage fed to the V_{contP} pin. That is, each of the first and the second bias control networks 300 and 310 alternates its operation mode between low and high input power drive modes, in accordance with the control voltage provided to the V_{conC} and V_{conP} pins, generates different base bias voltages in accordance with each operation mode and feeds the base bias voltages to the carrier amplifier 210 and the peaking amplifier 220 through the V_{refC} and V_{refP} pins, respectively.

The control voltages fed to the V_{contC} and V_{contP} pins vary with the power level of the input signal. For example, if the input signal has a power level lower than or equal to a predetermined threshold power level, a high voltage such as 2-3 V is fed to the first and the second bias control networks 300 and 310. Conversely, if the input signal has a power level higher than the predetermined threshold power, a low voltage such as 0 V is fed to the first and the second bias control networks 300 and 310.

When a high voltage is fed to the V_{contC} pin, the operation mode of the first bias network 300 is set to the low power drive mode, and, therefore, the bias voltage provided to the carrier amplifier 210 through the V_{refC} pin decreases. Then, collector idle currents of the transistors 212 and 214 are also reduced. Likewise, when a high voltage is applied to the V_{contP} pin, the operation mode of the second bias network 310 is changed to the low power drive mode. Thereafter, the transistors 222 and 224 are biased by the bias voltage supplied through the V_{refP} pin, and it makes the peaking amplifier 220 turned off.

On the other hand, when a low voltage 0 V is applied to the V_{contC} and V_{contP} pins, the first and the second bias control networks 300 and 310 respectively change their operation modes to the high power drive mode and provide both the carrier amplifier 210 and the peaking amplifier 220 with the base bias voltages through the V_{refC} and V_{refP} pin, to thereby bias the transistors 212, 214, 222 and 224. In this way, the carrier amplifier 210 and the peaking amplifier 220 function as class AB amplifiers, respectively. That is, when the input signal power level is below a predetermined threshold voltage (in case of the low power drive mode), only the carrier amplifier 210 functions as a conventional Doherty amplifier, entailing in a high efficiency. Further, when the input signal power level is above the predetermined threshold voltage (in case of the high power drive mode), both the carrier amplifier 210 and the peaking amplifier 220 function as class AB amplifiers, attaining a high efficiency and a high linearity, simultaneously.

As shown in FIG. 2, there are several matching circuits, i.e., the input matching circuits 211 and 221, the inter-stage matching circuits 213 and 223, and the output matching circuits 215 and 225 in the Doherty amplifier 200. The input matching circuits 211 and 221 perform a matching of the input signals of the transistors 212 and 222, respectively, and the inter-stage matching circuits 213 and 223 perform a matching of the output signals of the transistors 212 and 222, respectively. The output matching circuits 215 and 225 perform a matching of the output signals of the transistors 214 and 224, respectively.

The carrier amplifier 210 of the Doherty amplifier 200 amplifies signals attenuated at the attenuator 110 and outputs the amplified signals to the Doherty output network 400. Further, the peaking amplifier 220 amplifies the signals compensated at the first transmission line 120 and also outputs the amplified signals to the Doherty output network 400.

The Doherty output network 400, which includes a plurality of transmission lines having arbitrary lengths, combines the signals amplified at the carrier amplifier 210 and the peaking amplifier 220. In particular, the Doherty output network 400 includes a second transmission line 410 having characteristic impedance R_{oc} and phase θ_{c}, which is arranged at an output end of the carrier amplifier 210, a third transmission line 420 having characteristic impedance Rₒₚ and phase θ_{P}, which is arranged at an output end of the peaking amplifier 220 and a fourth transmission line 430 having characteristic impedance R_{oc} and phase 90°, which is coupled between the second transmission line 410 and the third transmission line 420. Herein, in order to perform a Doherty operation, the output of the carrier amplifier 210 should be matched with the characteristic impedance R_{oc} of the second transmission line 410, and the output of the peaking amplifier 220 should be also matched with the characteristic impedance Rₒₚ of the third transmission line 420. These transmission lines 410, 420 and 430 may be implemented by using lumped elements.

In the high power drive mode, the signal amplifier of the present invention having the above-mentioned structure is capable of reducing the optimum load impedances because the carrier amplifier 210 and the peaking amplifier 220 are operated as class AB amplifiers simultaneously. For adjusting the reduced optimum load impedance to 50 Ω at the output end of the amplifiers 210 and 220, the characteristic impedance of the second and third transmission lines 410 and 420 may be adjusted by using the following equations:

Rₒₚ50 (1+α) Eq. (1)

$${R}_{o c} = 50 \cdot \frac{1 + α}{α} \qquad Eq . ( 2 )$$

where α is a size ratio of the peaking amplifier 220 to the carrier amplifier 210. Accordingly, the Doherty output network 400 may prevent leakages from the output signal of the signal amplifier and achieves a desired load impedance without using an additional quarter-wave line at the output end of the Doherty output network 400. Further, the phases Θ_{C} and Θₚ of the second and third transmission lines 410 and 420 are determined by matching the resistive and reactive values of the load impedance, thereby obtaining a highest output power. A method for determining the phases Θ_{c} and Θₚ has suggested by Y. Yang, J. Yi, Y. Y. Woo, and B. Kim, in “Optimum Design for Linearity and Efficiency of a Microwave Doherty Amplifier using a New Load Matching Technique”, Microwave Journal, pp. 20-36, December 2001.

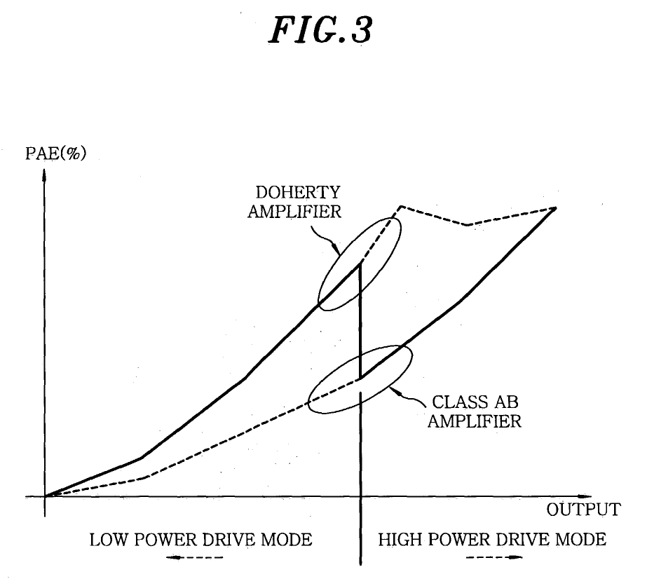

FIG. 3 shows a graph of power-added efficiency (PAE, %) versus output power level (dBm) for the signal amplifier in accordance with the present invention. In a low power region, since the carrier amplifier 210 functions as a conventional Doherty amplifier and the peaking amplifier 220 is pinched off when the input signal is below the predetermined threshold voltage, the efficiency diagram of the signal amplifier in accordance with the present invention shows the same graph as that of the conventional Doherty amplifier. Further, the carrier amplifier 210 and peaking amplifier 220 function as class AB amplifiers when the input signal is over the predetermined threshold voltage, so that the signal amplifier of the present invention has as high efficiency as a class AB amplifier in a high power region. Therefore, the graph showing PAE of the signal amplifier in accordance with the present invention is folded near the predetermined input power level and achieves high efficiency in a low input power level and also high efficiency and linearity in a high input power level at the same time. These characteristics are essential for a signal amplifier in a CDMA communications system for which a wide coverage of low power signal transmission is required. Further, by manipulating the characteristic impedance of the second and third transmission lines 410 and 420, an additional quarter-wave line, which is needed for adjusting the impedance reduction to 50 Ω in a conventional Doherty amplifier, can be eliminated and, thereby, a minimization of the signal amplifier circuit can be achieved.

While the invention has been shown and described with respect to the preferred embodiment, it will be understood by those skilled in the art that various changes and modifications may be made without departing from the spirit and scope of the invention as defined in the following claims.

What is claimed is:

1. A signal amplifier comprising:
a splitter for splitting an input signal into two signals to be transmitted respectively through a first and a second transmission paths;
a first and a second bias control networks for generating base bias signals corresponding to a power level of the input signal by alternating their operation modes, wherein the power level of the input signal lower than a predetermined threshold level is associated with a low input power drive mode and the power level of the input signal higher than the predetermined threshold level is associated with a high input power drive mode of the control networks;
a Doherty amplifier including a carrier amplifier for amplifying the signal transmitted through the first transmission path and a peaking amplifier for amplifying the signal transmitted through the second transmission path; and
a Doherty output network for matching and outputting the signals amplified at the carrier amplifier and the peaking amplifier.

2. The signal amplifier of claim 1, wherein the carrier amplifier reduces idle current in the low input power drive mode and functions as a class AB amplifier in the high input power drive mode in accordance with the bias signal transmitted from the first bias control network; and
the peaking amplifier is turned off in the low input power drive mode and functions as a class AB amplifier in the high input power drive mode in accordance with the bias signal transmitted from the second bias control network.

3. The signal amplifier of claim 1, wherein the first bias control network includes a V_{contC} pin for receiving different control voltages depending on the power level of the input signal and a V_{refC} pin for transmitting the different base bias signal to the carrier amplifier in accordance with the control voltage fed to the V_{contC} pin; and
the second bias control network includes a V_{contP} pin for receiving different control voltages depending on the power level of the input signal and a V_{refP} pin for transmitting the different base bias signal to the peaking amplifier in accordance with the control voltage fed to the V_{contP} pin.

4. The signal amplifier of claim 3, wherein the control voltages fed to the V_{contC} pin is equal to that of the V_{contP} pin.

5. The signal amplifier of claim 4, wherein the V_{contC} pin and the V_{contP} pin are fed with about 2˜3 V in the low input power drive mode and about 0 V in the high input power drive mode.

6. The signal amplifier of claim 1, further comprising an attenuator for compensating a gain difference between the first and the second transmission paths in the high input power drive mode, which is located at one of input ends of the carrier amplifier and the peaking amplifier.

7. The signal amplifier of claim 6, wherein the attenuator is implemented by using passive elements or variable gain amplifiers (VGAs).

8. The signal amplifier of claim 1, further comprising a first transmission line for compensating a delay and a phase differences between the first and the second transmission paths.

9. The signal amplifier of claim 8, wherein the first transmission line is implemented by using lumped elements.

10. The signal amplifier of claim 1, wherein the Doherty output network includes:
a second transmission line having characteristic impedance R_{oc} and phase Θ_{c}, which is arranged at an output end of the carrier amplifier;
a third transmission line having characteristic impedance Rₒₚ and phase Θₚ, which is arranged at an output end of the peaking amplifier; and
a fourth transmission line having characteristic impedance R_{oc} and phase 90°, which is coupled with the second transmission line.

11. The signal amplifier 10, wherein the second, the third and the fourth transmission lines are implemented by using lumped elements.

12. The signal amplifier of claim 10, wherein the characteristic impedance Rₒₚ is adjusted in accordance with the formula of Rop=50·(1+α), where α is a size ratio of the peaking amplifier to the carrier amplifier.

13. The signal amplifier of claim 10, wherein the characteristic impedance R_{oc} is adjusted in accordance with the formula of
$$R o c = 50 \cdot \frac{1 + α}{α} ,$$
where α is a size ratio of the peaking amplifier to the carrier amplifier.
